(19) United States
(12) Patent Application Publication
(10) Pub. No.: US 2026/0280523 A1
(43) Pub. Date: Sep. 17, 2026

(54) ELASTIC WAVE DEVICE AND COMMUNICATION APPARATUS

(71) Applicant: KYOCERA CORPORATION, Kyoto-shi, Kyoto (JP)

(72) Inventor: Soichiro NOZOE, Kyoto-shi, Kyoto (JP)

(73) Assignee: KYOCERA CORPORATION, Kyoto-shi, Kyoto (JP)

(21) Appl. No.: 18/872,198

(22) PCT Filed: May 25, 2023
(86) PCT No.: PCT/JP2023/019449

§ 371 Date: Dec. 5, 2024

(30) Foreign Application Priority Data
Jun. 17, 2022 (JP) 2022-098302

(51) Int. Cl. H03H 9/25; H03H 9/145

(52) U.S. Cl. CPC H03H 9/25; H03H 9/145

(57) ABSTRACT

To reduce a spurious signal. A support substrate in which a cavity portion is formed, a piezoelectric substrate located over the instruction substrate and covering the cavity portion, and an IDT electrode located on the piezoelectric substrate are provided. The IDT electrode includes bus bars; a plurality of electrode fingers; and a first region sandwiched between the bus bars. The cavity portion overlaps with the entirety of an intersecting region where the plurality of electrode fingers overlap with each other in plane perspective. The first region includes a low acoustic velocity region extending in the arrangement direction of the plurality of electrode fingers. An outer edge of the cavity portion and the low acoustic velocity region overlap with each other in plane perspective.

### TECHNICAL FIELD

The present disclosure relates to an elastic wave device.

### BACKGROUND OF INVENTION

Patent Document 1 discloses a structural example of an elastic wave device having a membrane structure.

### CITATION LIST

### Patent Literature

Patent Document 1: JP 2012-257019 A

### SUMMARY

To solve the above problems, in an aspect of the present disclosure, an elastic wave device includes a support substrate provided with a cavity portion; a piezoelectric substrate located over the instruction substrate and covering the cavity portion; and an IDT electrode located on the piezoelectric substrate. The IDT electrode includes bus bars; a plurality of electrode fingers; and a first region sandwiched between the bus bars. The cavity portion overlaps with the entirety of an intersecting region where the plurality of electrode fingers overlap with each other in plane perspective. The first region includes a low acoustic velocity region extending in an arrangement direction of the plurality of electrode fingers. An outer edge of the cavity portion and the low acoustic velocity region overlap with each other in plane perspective.

### BRIEF DESCRIPTION OF THE DRAWINGS

FIG. 1 is a view illustrating a part of an elastic wave device according to a first embodiment in plan view.

FIG. 2 is a cross-sectional view of the elastic wave device according to the first embodiment.

FIG. 3 is a frequency characteristic when a position of an outer edge coincides with an end portion of a bus bar.

FIG. 4 is a frequency characteristic when the position of the outer edge is located below the inside of the bus bar.

FIG. 5 is a frequency characteristic when the position of the outer edge is located below the inside of a dummy electrode finger.

FIG. 6 is a frequency characteristic when the position of the outer edge is located at an end portion of an intersecting region.

FIG. 7 is a frequency characteristic when the position of the outer edge is located at an end portion of a low acoustic velocity region.

FIG. 8 is a graph illustrating a transverse mode index depending on a silicon extension amount in the elastic wave device according to the first embodiment.

FIG. 9 is a phase average value from a resonant frequency to an anti-resonant frequency depending on the silicon extension amount in the elastic wave device according to the first embodiment.

FIG. 10 is a cross-sectional view of an elastic wave device according to a second embodiment.

FIG. 11 is a graph illustrating a transverse mode index depending on the silicon extension amount in the elastic wave device according to the second embodiment.

FIG. 12 is a phase average value from the resonant frequency to the anti-resonant frequency depending on the silicon extension amount in the elastic wave device according to the second embodiment.

FIG. 13 is a cross-sectional view of an elastic wave device according to a third embodiment.

FIG. 14 is a graph illustrating a transverse mode index depending on the silicon extension amount in the elastic wave device according to the third embodiment.

FIG. 15 is a phase average value from the resonant frequency to the anti-resonant frequency depending on the silicon extension amount in the elastic wave device according to the third embodiment.

FIG. 16 is a cross-sectional view of an elastic wave device according to a fourth embodiment.

FIG. 17 is a graph illustrating a transverse mode index depending on the silicon extension amount in the elastic wave device according to the fourth embodiment.

FIG. 18 is a phase average value from the resonant frequency to the anti-resonant frequency depending on the silicon extension amount in the elastic wave device according to the fourth embodiment.

FIG. 19 is a graph illustrating a transverse mode index depending on the silicon extension amount in an elastic wave device according to a fifth embodiment.

FIG. 20 is a phase average value from the resonant frequency to the anti-resonant frequency depending on the silicon extension amount in the elastic wave device according to the fifth embodiment.

FIG. 21 is a graph illustrating a transverse mode index depending on the silicon extension amount in an elastic wave device according to a sixth embodiment.

FIG. 22 is a phase average value from the resonant frequency to the anti-resonant frequency depending on the silicon extension amount in the elastic wave device according to the sixth embodiment.

FIG. 23 is a graph illustrating a transverse mode index depending on a width of the bus bar in an elastic wave device according to a seventh embodiment.

FIG. 24 is a phase average value from the resonant frequency to the anti-resonant frequency depending on the width of the bus bar in the elastic wave device according to the seventh embodiment.

FIG. 25 is a plan view of an elastic wave device according to an eighth embodiment.

FIG. 26 is a graph illustrating a transverse mode index T depending on the silicon extension amount in the elastic wave device according to the eighth embodiment.

FIG. 27 is a phase average value from the resonant frequency to the anti-resonant frequency depending on the silicon extension amount in the elastic wave device according to the eighth embodiment.

FIG. 28 is a diagram illustrating a schematic configuration of a communication apparatus according to a ninth embodiment.

FIG. 29 is a plan view of one cycle of an IDT electrode in a typical elastic wave device.

FIG. 30 is a cross-sectional view of the typical elastic wave device.

FIG. 31 is a diagram illustrating a frequency characteristic in a typical elastic wave device according to a first comparative example.

FIG. 32 is a diagram illustrating a frequency characteristic in an elastic wave device according to a second comparative example.

### DESCRIPTION OF EMBODIMENTS

A filter characteristic with a reduced spurious signal is desirable to be achieved in an elastic wave device having a membrane structure.

### First Embodiment

An elastic wave device according to a first embodiment will be described below. For convenience of description, a component having the same function as that described in the first embodiment will be denoted by the same reference sign in each of subsequent embodiments, and a description thereof will not be repeated. For simplicity, descriptions of known technical matters will be omitted as appropriate. Each component, material, and numerical value described herein are examples only, unless otherwise inconsistent. Thus, for example, unless otherwise inconsistent, the positional relationship of each component is not limited to the examples in each drawing. The illustration of each component is not necessarily to scale.

### Comparative Example: Structure of Typical IDT Electrode 600

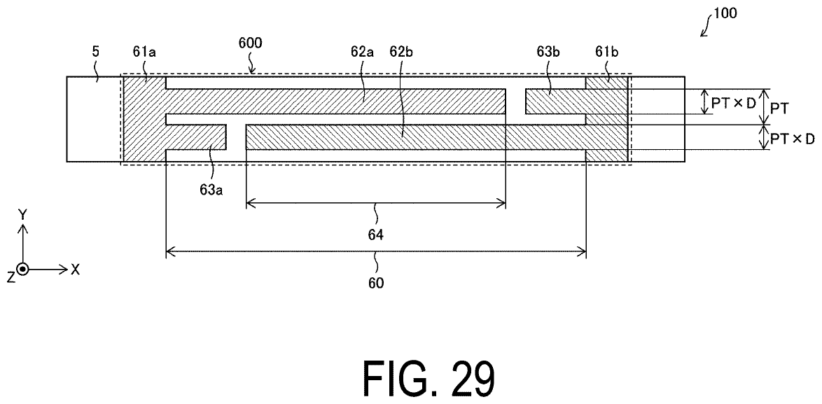

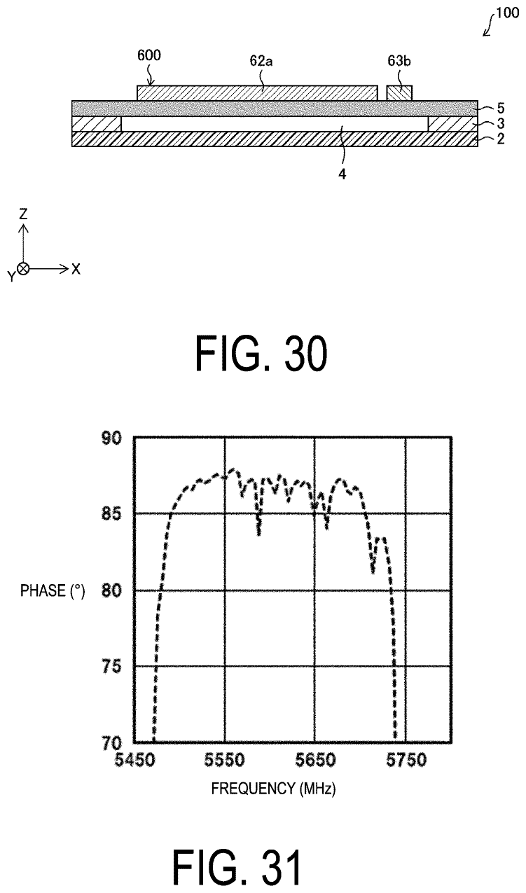

Prior to a description of the first embodiment, a typical elastic wave device will be described. FIG. 29 is a plan view of one cycle of an IDT electrode 600 in a typical elastic wave device 100. Thus, the IDT electrodes 600 are arranged in the arrangement direction (Y direction) of the electrode fingers. FIG. 30 is a cross-sectional view of the typical elastic wave device 100.

In the elastic wave device 100, a silicon 3 is partially formed on a support 2 composed of various materials. The material of the support 2 may be, for example, silicon, or other material. The support 2, when silicon, may be bonded to the silicon 3 or may be formed integrally. The silicon 3 is used for support without using the support 2. A region where the silicon 3 is not formed relative to the support 2 is a cavity portion 4. The support 2 may have an opening in a region that overlaps with the cavity portion 4 in plan view. The support 2 and the silicon 3 may be collectively referred to as a support substrate. In the elastic wave device 100, a piezoelectric substrate 5 is further formed on the silicon 3 and the cavity portion 4, and the piezoelectric substrate 5 covers the cavity portion 4. The piezoelectric substrate 5 is formed of 105° Y-X LiNb₃ or the like. 105° Y-X LiNb₃ is also called 105° rotated Y-cut X-propagation LiNb₃.

The elastic wave device 100 includes the IDT electrode 600 formed in the region corresponding to the cavity portion 4 further on the piezoelectric substrate 5. The IDT electrode 600 includes pairs of: a bus bar 61a and a bus bar 61b; an electrode finger 62a and an electrode finger 62b; a dummy electrode finger 63a and a dummy electrode finger 63b (each also called a second electrode finger).

Each member of each pair is applied with different potential from each other. Hereinafter, when the different potentials are not considered, the above pairs are referred to as a bus bar 61, an electrode finger 62, and a dummy electrode finger 63. An elastic wave of an A1 mode Lamb wave is excited in the piezoelectric substrate 5 by the IDT electrode 600.

An elastic wave of a bulk wave may be excited in the piezoelectric substrate 5 by the IDT electrode 600. A bulk wave of a Thickness Shear Mode may be excited.

In the IDT electrode 600, the electrode finger 62 and the dummy electrode finger 63 are alternately connected to the bus bar 61. The electrode finger 62 is an electrode long in the X direction, and the dummy electrode finger 63 is an electrode short in the X direction. The electrode finger 62a and the dummy electrode finger 63b face each other, and the electrode finger 62b and the dummy electrode finger 63a face each other. A region sandwiched between the bus bars 61 is called a first region 60. Accordingly, the electrode finger 62 and the dummy electrode finger 63 are located in the first region 60.

The region where the electrode finger 62a and the electrode finger 62b overlap with each other is an intersecting region 64. For example, a plate wave is excited in the piezoelectric substrate 5 in the intersecting region 64 by the IDT electrode 600 applied with AC to the electrode finger 62a and the electrode finger 62b.

The distance from the upper end in the arrangement direction of the electrode finger of the electrode finger 62a to the upper end in the arrangement direction of the electrode finger of the electrode finger 62b in the intersecting region 64 is called a pitch PT, and the ratio of the width of the electrode finger 62 to the pitch PT is called a duty D.

### First Comparative Example: Frequency Characteristic of Typical IDT Electrode 600

FIG. 31 is a diagram illustrating a frequency characteristic of the typical elastic wave device 100 according to a first comparative example. In FIG. 31, the horizontal axis represents the frequency, and the vertical axis represents the phase. In the elastic wave device 100, the phase may be constant, 90°.

As illustrated in FIG. 31, for example, the phase rapidly decreases near about 5590 MHz and about 5655 MHz. Such an undesired abrupt change in the phase with respect to the frequency may be called a spurious signal. A spurious signal occurs in the elastic wave device 100. Hereinafter, the superiority of the elastic wave device based on the configuration of the present disclosure will be illustrated as compared with FIG. 31.

### Second Comparative Example: Frequency Characteristic when Silicon 3 Extends Below IDT Electrode 600

In an elastic wave device according to the second comparative example, the cavity portion 4 is smaller than that in the elastic wave device 100, and the silicon 3 extends below the IDT electrode 600. That is, an outer edge 4a of the cavity portion 4 is located below the IDT electrode 600. In the elastic wave device according to the second comparative example, a duty of the electrode finger is constant from the root to the front end. The dummy electrode finger also has the same duty as the electrode finger. Such an elastic wave device is also called a non-duty offset resonator or a normal resonator.

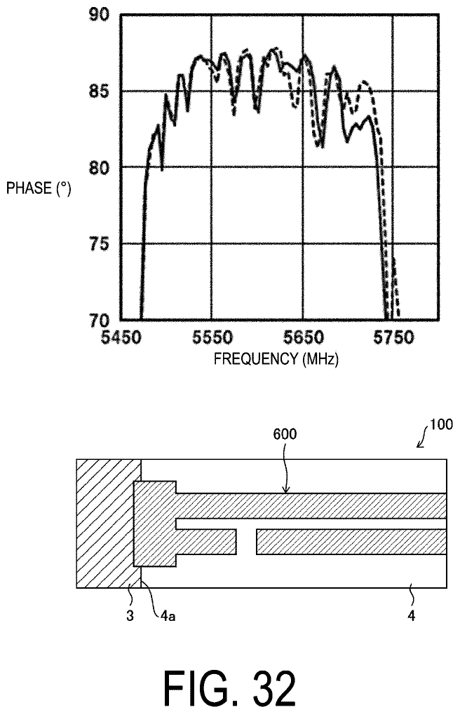

FIG. 32 is a diagram illustrating a frequency characteristic of the elastic wave device according to the second comparative example. In the upper graph of FIG. 32, the horizontal axis represents the frequency, and the vertical axis represents the phase. The solid line represents the frequency characteristic of the elastic wave device according to the second comparative example when the silicon 3 extends below the IDT electrode 600, and the dashed line represents the frequency characteristic of the elastic wave device according to the second comparative example when the silicon 3 does not extend below the IDT electrode 600. The lower schematic diagram of FIG. 32 illustrates the extension amount of the silicon 3. In the case of the solid line, the extension amount of the silicon 3 is 0.5 μm. 0.5 μm corresponds to ⅓ of the thickness of the bus bar.

As illustrated in FIG. 32, the frequency characteristic of the second comparative example is found to be not much different from that of the first comparative example, and a spurious signal is generated.

### Configuration of IDT Electrode 6

After describing the shape of the IDT electrode according to the first embodiment, description will show that reduction of the spurious signal has been enabled by the IDT electrode.

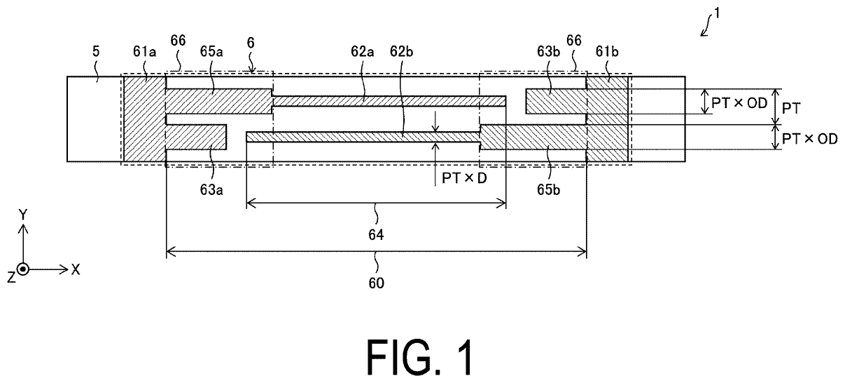

FIG. 1 is a view illustrating a part of an elastic wave device 1 according to the first embodiment in plan view. The elastic wave device 1 differs from the elastic wave device 100 in that the IDT electrode 6 is formed instead of the IDT electrode 600.

The IDT electrode 6 includes pairs of: the bus bar 61a and the bus bar 61b; the electrode finger 62a and the electrode finger 62b; the dummy electrode finger 63a and the dummy electrode finger 63b; and widened portions 65a and 65b (each also called a widened portion 65). Each member of each pair is applied with different potential from each other. The widened portion 65 is located near the bus bar 61 in the first region 60.

The widened portion 65 located near the bus bar 61 may be located in a range within 1 wavelength from the bus bar-side edge of the intersecting region 64 or in a range of the pitch PT.

In the IDT electrode 6, the widened portion 65 and the dummy electrode finger 63 are alternately connected to the bus bar 61, and the electrode finger 62 is connected to the widened portion 65. The state that the electrode finger 62 and the dummy electrode finger 63 face to each other is the same.

The ratio of the width to the pitch PT at the widened portion 65, is called an offset duty OD, which is larger than the duty D. That is, the width of the widened portion 65 in the Y direction (the direction in which the electrode fingers are arranged) is larger (widened) than the width of the electrode finger 62 in the Y direction. The length of the widened portion 65 in the X direction (the direction in which the electrode fingers are extended) is longer than the length of the dummy electrode finger 63. The IDT electrode 6 having such a widened portion 65 is called a duty offset resonator. The dummy electrode finger (second electrode finger) 63 has a width larger than the average width of the electrode finger 62.

A region extending in the arrangement direction of the electrode finger 62 in the width of the widened portion 65 is called a low acoustic velocity region 66. Since the offset duty OD of the widened portion 65 is larger than the duty D of the electrode finger 62, the weight per unit area at the widened portion 65 is larger than that at the electrode finger 62. Accordingly, the acoustic velocity in the low acoustic velocity region 66 is lower among the first region 60.

### Frequency Characteristic for Each Cross-Sectional Shape of IDT Electrode 6

In the comparative examples, the IDT electrode 600 is arranged above the region corresponding to the cavity portion 4, but the IDT electrode 6 is not limited to this. Specifically, in the elastic wave device 1 according to the first embodiment, the silicon 3 extends below the IDT electrode 6, and the outer edge 4a is disposed below the IDT electrode 6. As described below, in the elastic wave device 1, the outer edge 4a of the cavity portion 4 overlaps with the low acoustic velocity region 66 in plane perspective.

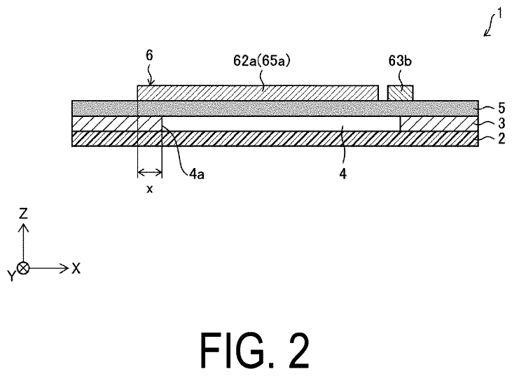

FIG. 2 is a cross-sectional view of the elastic wave device 1 according to the first embodiment. In FIG. 2, unlike FIG. 30, the silicon 3 extends below the IDT electrode 6. The extension amount is defined as a silicon extension amount x. This x is a distance from the end portion of the bus bar 61 outside the first region 60 to the outer edge 4a of the cavity portion 4. The silicon extension amount x is a variable, and the frequency characteristic of the elastic wave device was simulated while adjusting the silicon extension amount x. In the IDT electrode 6, the duty D is set as 0.5 and the offset duty OD is set as 0.6.

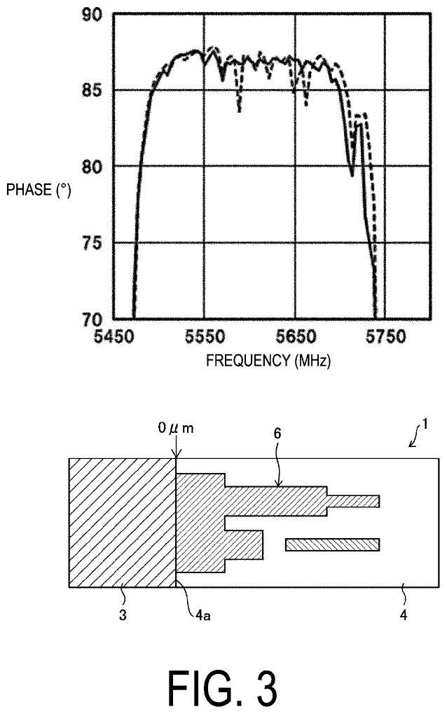

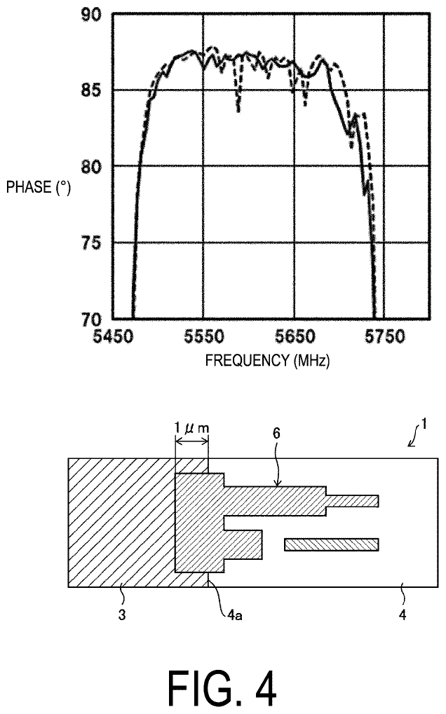

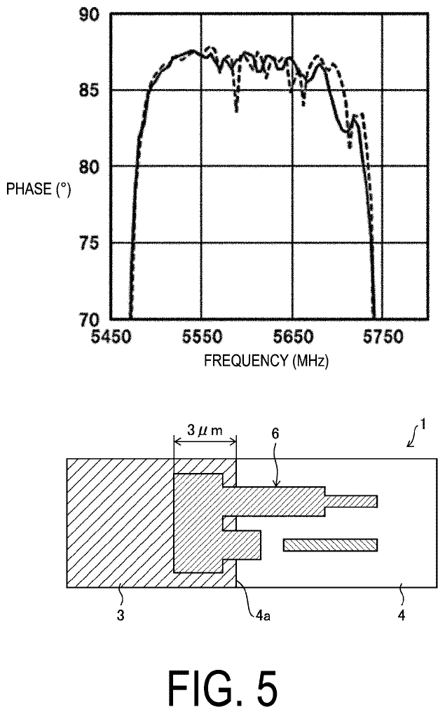

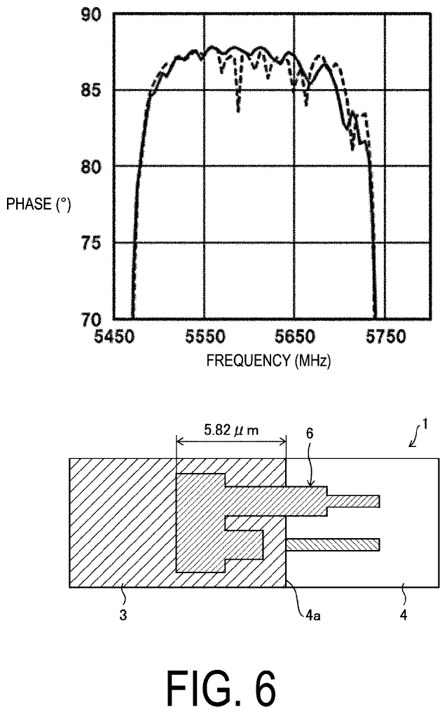

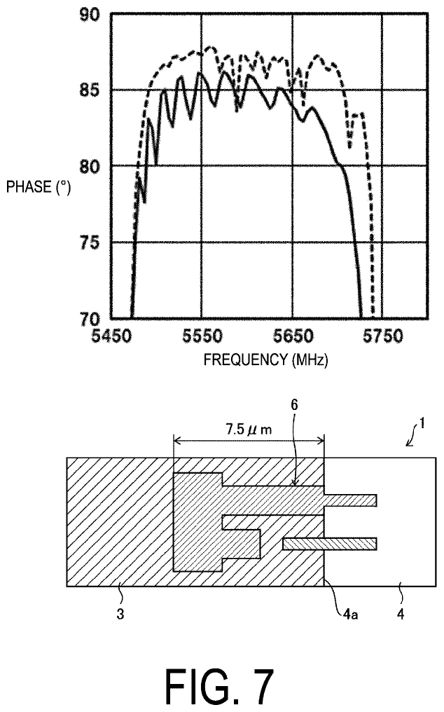

FIG. 3 illustrates a frequency characteristic when the position of the outer edge 4a coincides with the end portion of the bus bar 61. FIG. 4 is a frequency characteristic when the position of the outer edge 4a is located below the inside of the bus bar 61. FIG. 5 is a frequency characteristic when the position of the outer edge 4a is located below the inside of the dummy electrode finger 63. FIG. 6 is a frequency characteristic when the position of the outer edge 4a is located at the end portion of the intersecting region 64. FIG. 7 illustrates a frequency characteristic when the position of the outer edge 4a is located at the end portion of the widened portion 65.

In the respective upper graphs of FIGS. 3 to 7, the dashed line represents the frequency characteristic in the case of first comparative example, and the solid lines represent the respective cases. The respective lower schematic diagrams of FIGS. 3 to 7 illustrate the extension amount of the silicon 3. As illustrated in FIGS. 3 to 7, the frequency characteristic changes according to the silicon extension amount x of the silicon 3 below the IDT electrode 6.

As illustrated in FIGS. 3 to 7, from the case with a position of the outer edge 4a coinciding with the end portion of the bus bar 61 to the case with the position located at the end portion of the low acoustic velocity region, the spurious signal can be seen to be reduced.

### Introduction of Transverse Mode Index

In order to quantify the frequency characteristic depending on the silicon extension amount x of the silicon 3 below the IDT electrode 6, a transverse mode index T is introduced. The transverse mode index T can be expressed by the following equation.

$$T = \frac{{\int }_{f r}^{f α} \sqrt{{( \frac{dP}{df} )}^{2}} df}{Δ f} \qquad [ Math 1 ]$$

where P is a phase and f is a frequency. Δf is the difference between the anti-resonant frequency fa and the resonant frequency fr.

Since dP/df is a phase inclination, the transverse mode index T is the absolute value of the inclination per unit frequency within a pass band. Accordingly, the larger the transverse mode index T, the less flat the phase characteristic within the pass band and the more significant the spurious signal. The inventor searched the region where the transverse mode index T was small.

### Frequency Characteristic

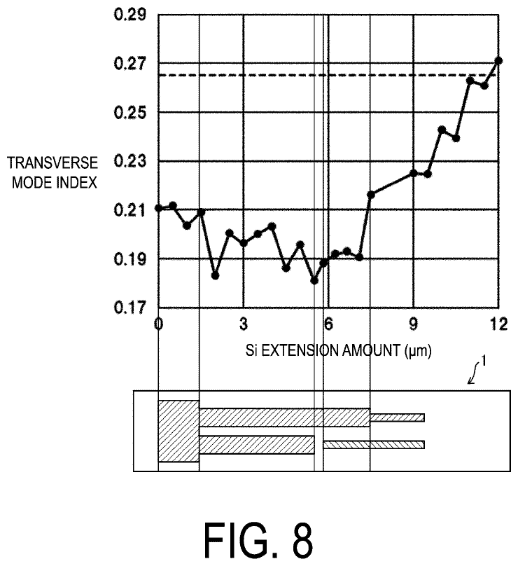

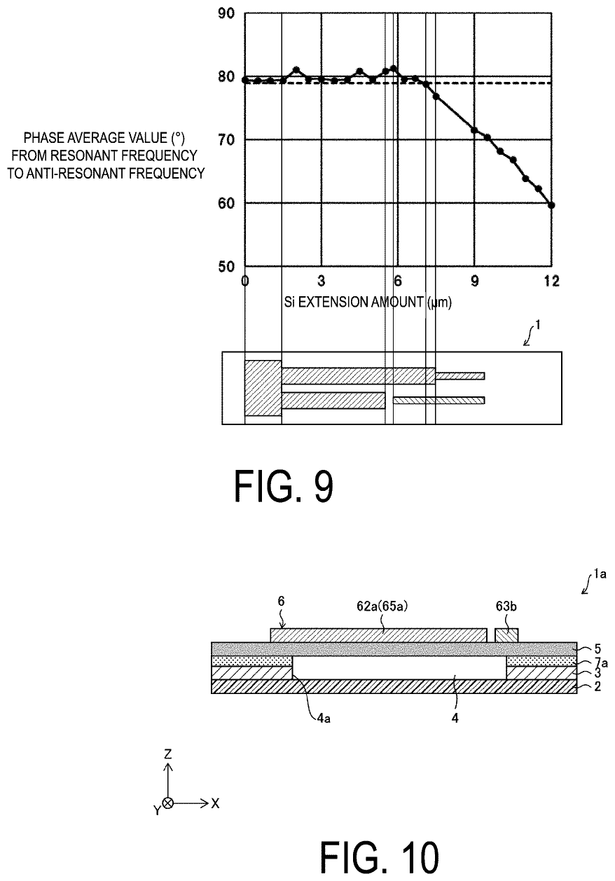

FIG. 8 is a graph illustrating a transverse mode index T depending on the silicon extension amount x in the elastic wave device 1 according to the first embodiment. FIG. 9 is a phase average value from the resonant frequency fr to the anti-resonant frequency fa depending on the silicon extension amount x in the elastic wave device 1 according to the first embodiment. The dashed lines in FIGS. 8 and 9 are the values in the comparative examples, and the solid lines are the values in the elastic wave device 1 according to the first embodiment. FIGS. 8 and 9 are graphs summarizing the frequency characteristics in FIGS. 3 to 7 for each index.

As illustrated in FIG. 8, the transverse mode index T indicates to be sufficiently small as compared with the comparative examples until the position of the outer edge 4a reaches the end portion of the low acoustic velocity region 66. As illustrated in FIG. 9, the phase average value indicates to be sufficiently close to 90° until the position of the outer edge 4a reaches the end portion of the low acoustic velocity region 66. Thus, in the elastic wave device 1 according to the first embodiment, the frequency characteristic is determined to be sufficiently good until the position of the outer edge 4a reaches the end portion of the low acoustic velocity region 66.

### Brief Summary

With respect to the duty offset resonator having the low acoustic velocity region 66 such as the elastic wave device 1 according to the first embodiment, investigation was performed that the frequency characteristic changes when the silicon 3 extends below the duty offset resonator. Specifically, the case was investigated where the outer edge 4a was located from the end portion of the bus bar 61 outside the first region 60 to the range of the first region 60.

As a result, in the duty offset resonator, the frequency characteristic was found to be sufficiently good when the location of the outer edge 4a (the edge relative to the cavity portion 4) is located in the range from the end portion of the bus bar 61 in the low acoustic velocity region 66 to the end portion of the low acoustic velocity region 66. FIGS. 3 to 7 indicate that the spurious signal can be reduced.

### Second Embodiment

FIG. 10 is a cross-sectional view of an elastic wave device 1a according to a second embodiment. The elastic wave device 1a is different from the elastic wave device 1 in that a connection layer 7a of silicon dioxide (SiO₂) is provided between the silicon 3 and the piezoelectric substrate 5. The connection layer 7a is located only on the silicon 3 and not located on the cavity portion 4. The connection layer 7a has a thickness of about 0.1 μm.

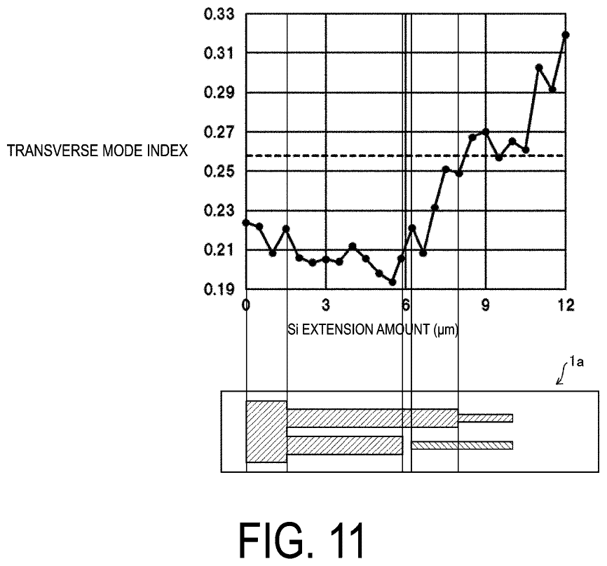

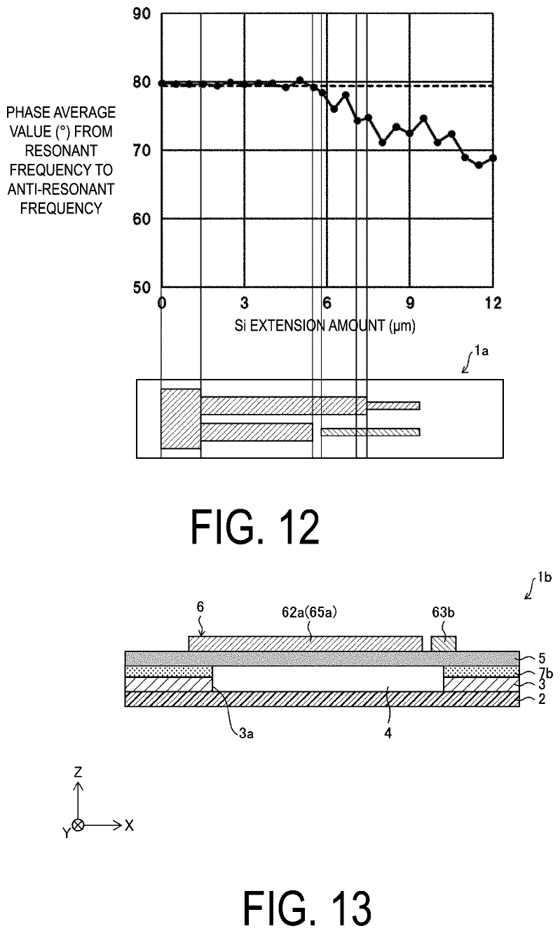

FIG. 11 is a graph illustrating a transverse mode index T depending on the silicon extension amount x in the elastic wave device 1a according to the second embodiment. FIG. 12 is a phase average value from the resonant frequency fr to the anti-resonant frequency fa depending on the silicon extension amount x in the elastic wave device 1a according to the second embodiment. The dashed lines in FIGS. 11 and 12 are the values in the first comparative example, and the solid lines are the values in the elastic wave device 1a according to the second embodiment.

As illustrated in FIG. 11, the transverse mode index T is found to be sufficiently small as compared with the first comparative example until the outer edge 4a reaches the end portion of the low acoustic velocity region 66. As illustrated in FIG. 12, a phase average value is found to be sufficiently close to 90° until the outer edge 4a reaches the end portion of the low acoustic velocity region 66. Thus, in the elastic wave device 1a according to the second embodiment, the frequency characteristic is determined to be sufficiently good until the position of the outer edge 4a reaches the end portion of the low acoustic velocity region 66.

### Third Embodiment

FIG. 13 is a cross-sectional view of an elastic wave device 1b according to a third embodiment. The elastic wave device 1b differs from the elastic wave device 1 in that a connection layer 7b of a low resistance layer is provided between the silicon 3 and the piezoelectric substrate 5. The connection layer 7b is located only on the silicon 3 and not located on the cavity portion 4.

The low resistance layer is an interface that degrades characteristic at the interface to be bonded. The low resistance layer is a compound of such as lithium, niobium, silicon, and oxygen. The thickness of the low resistance layer is about 2 nm and has a resistivity of, for example, about 2.5 Ω·cm at a frequency of about 5500 MHz.

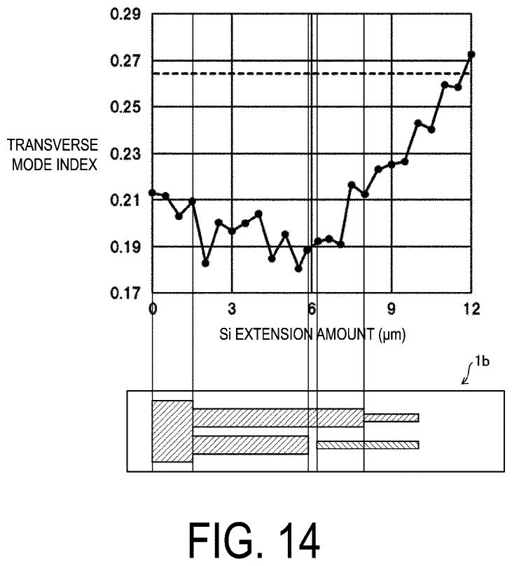

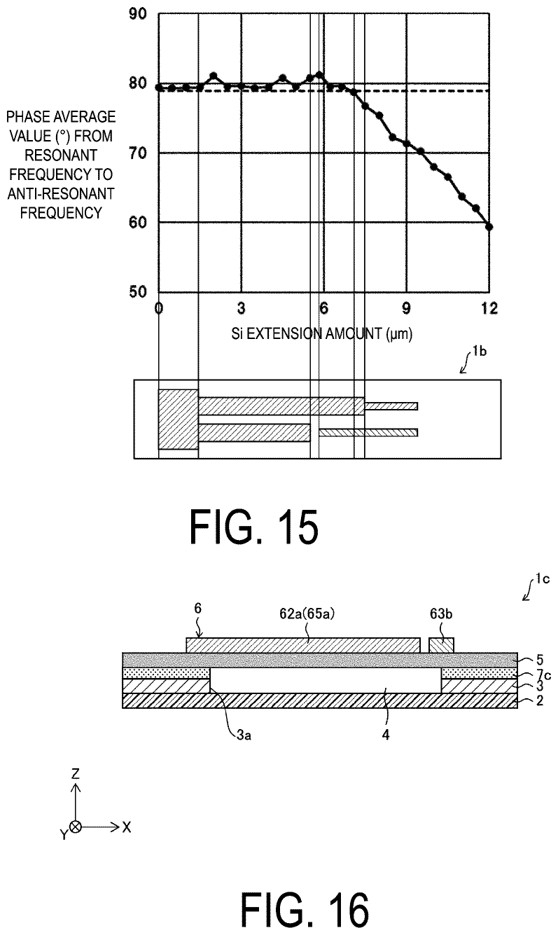

FIG. 14 is a graph illustrating a transverse mode index T depending on the silicon extension amount x in the elastic wave device 1b according to the third embodiment. FIG. 15 is a phase average value from the resonant frequency fr to the anti-resonant frequency fa depending on the silicon extension amount x in the elastic wave device 1b according to the third embodiment. The dashed lines in FIGS. 14 and 15 are the values in the first comparative example, and the solid lines are the values in the elastic wave device 1b according to the third embodiment.

As illustrated in FIG. 14, the transverse mode index T is found to be sufficiently small as compared with the first comparative example until the outer edge 4a reaches the end portion of the low acoustic velocity region 66. As illustrated in FIG. 15, the phase average value is found to be sufficiently close to 90° until the outer edge 4a reaches the end portion of the low acoustic velocity region 66. Thus, in the elastic wave device 1b according to the third embodiment, the frequency characteristic is determined to be sufficiently good until the position of the outer edge 4a reaches the end portion of the low acoustic velocity region 66.

### Fourth Embodiment

FIG. 16 is a cross-sectional view of an elastic wave device 1c according to a fourth embodiment. The elastic wave device 1c differs from the elastic wave device 1 in that a connection layer 7c of aluminum nitride (AlN) is provided between the silicon 3 and the piezoelectric substrate 5. The connection layer 7c is located only on the silicon 3 and not located on the cavity portion 4. The connection layer 7c has a thickness of about 0.1 μm.

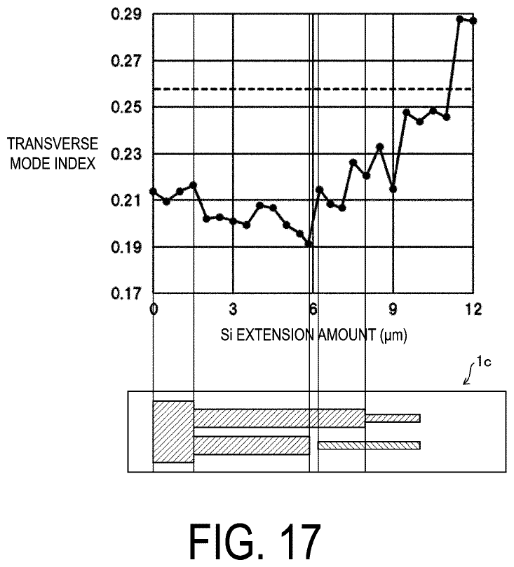

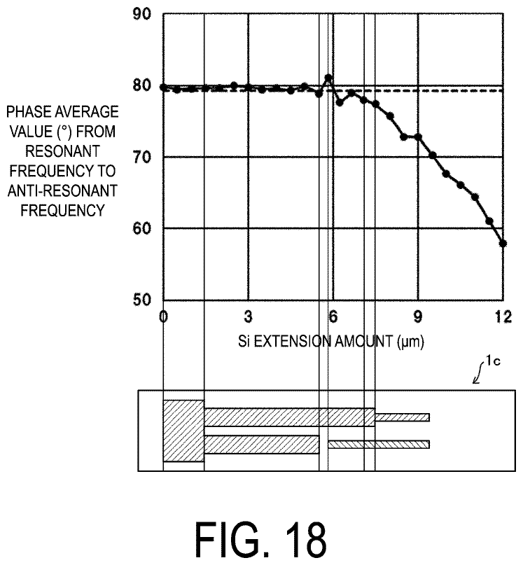

FIG. 17 is a graph illustrating a transverse mode index T depending on the silicon extension amount x in the elastic wave device 1c according to the fourth embodiment. FIG. 18 is a phase average value from the resonant frequency fr to the anti-resonant frequency fa depending on the silicon extension amount x in the elastic wave device 1c according to the fourth embodiment. The dashed lines in FIGS. 17 and 18 are the values in the first comparative example, and the solid lines are the values in the elastic wave device 1c according to the fourth embodiment.

As illustrated in FIG. 17, the transverse mode index T is found to be sufficiently small as compared with the first comparative example until the outer edge 4a reaches the end portion of the low acoustic velocity region 66. As illustrated in FIG. 18, the phase average value is found to be sufficiently close to 90° until the outer edge 4a reaches the end portion of the low acoustic velocity region 66. Thus, in the elastic wave device 1c according to the fourth embodiment, the frequency characteristic is determined to be sufficiently good until the position of the outer edge 4a reaches the end portion of the low acoustic velocity region 66.

### Fifth Embodiment

In an elastic wave device 1d according to a fifth embodiment, the offset duty OD of the IDT electrode 6 is increased to 0.7 with respect to the elastic wave device 1. That is, the weight of the low acoustic velocity region 66 is increased.

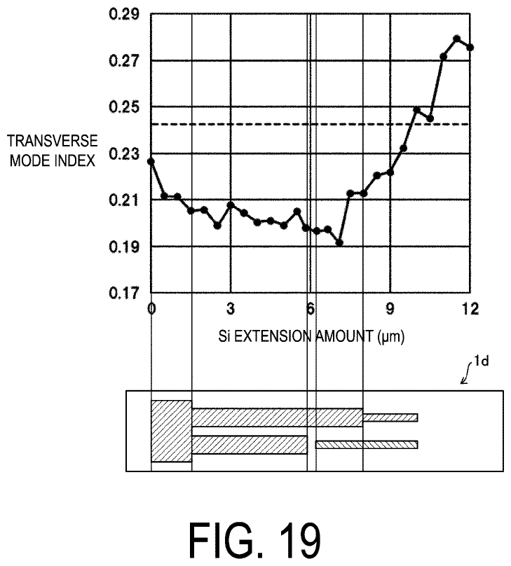

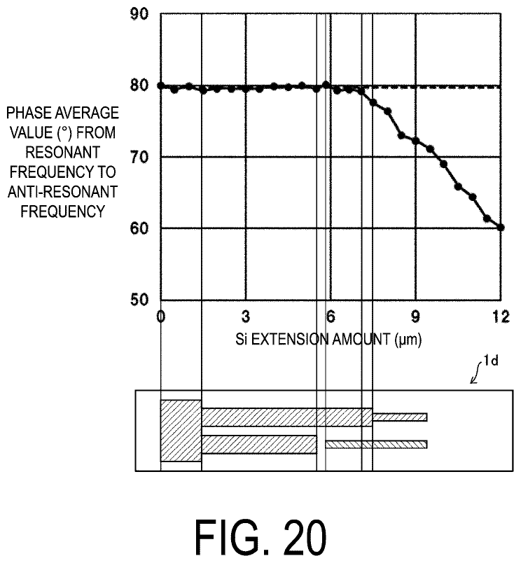

FIG. 19 is a graph illustrating a transverse mode index T depending on the silicon extension amount x in the elastic wave device in the fifth embodiment. FIG. 20 is a phase average value from the resonant frequency fr to the anti-resonant frequency fa depending on the silicon extension amount x in the elastic wave device according to the fifth embodiment. The dashed lines in FIGS. 19 and 20 are the values in the first comparative example, and the solid lines are the values in the elastic wave device according to the fifth embodiment.

As illustrated in FIG. 19, the transverse mode index T is found to be sufficiently small as compared with the first comparative example until the outer edge 4a reaches the end portion of the low acoustic velocity region 66. As illustrated in FIG. 20, the phase average value is found to be sufficiently close to 90° until the outer edge 4a reaches the end portion of the low acoustic velocity region 66. Thus, in the elastic wave device according to the fifth embodiment, the frequency characteristic is determined to be sufficiently good until the outer edge 4a reaches the end portion of the low acoustic velocity region 66.

In the first embodiment and the fifth embodiment, only the value of the offset duty OD is different, but the rest is the same, which indicate that even when the offset duty OD is increased, a good frequency characteristic could be obtained.

### Sixth Embodiment

In an elastic wave device 1e according to a sixth embodiment, the offset duty OD of the IDT electrode 6 is increased to 0.8 with respect to the elastic wave device 1. That is, the weight of the low acoustic velocity region 66 is increased.

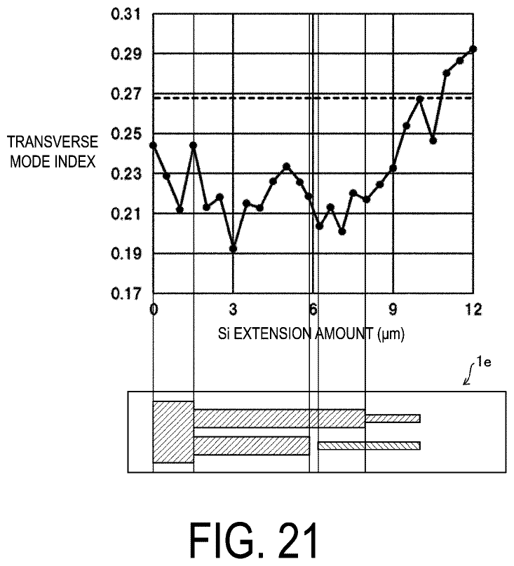

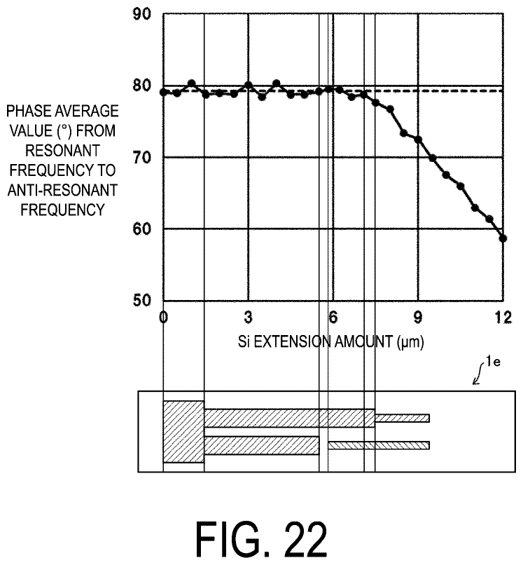

FIG. 21 is a graph illustrating a transverse mode index T depending on the silicon extension amount X in the elastic wave device according to a sixth embodiment. FIG. 22 is a phase average value from the resonant frequency fr to the anti-resonant frequency fa depending on the silicon extension amount x in the elastic wave device according to the sixth embodiment. The dashed lines in FIGS. 21 and 22 are the values in the first comparative example, and the solid lines are the values in the elastic wave device according to the fifth embodiment.

As illustrated in FIG. 21, the transverse mode index T is found to be sufficiently small as compared with the first comparative example until the outer edge 4a reaches the end portion of the low acoustic velocity region 66. As illustrated in FIG. 22, the phase average value is found to be sufficiently close to 90° until the outer edge 4a reaches the end portion of the low acoustic velocity region 66. Thus, in the elastic wave device according to the fifth embodiment, the frequency characteristic is determined to be sufficiently good until the outer edge 4a reaches the end portion of the low acoustic velocity region 66.

In the first embodiment and the sixth embodiment, only the value of the offset duty OD is different, but the rest is the same, which indicate that even when the offset duty OD is increased, a good frequency characteristic could be obtained.

### Seventh Embodiment

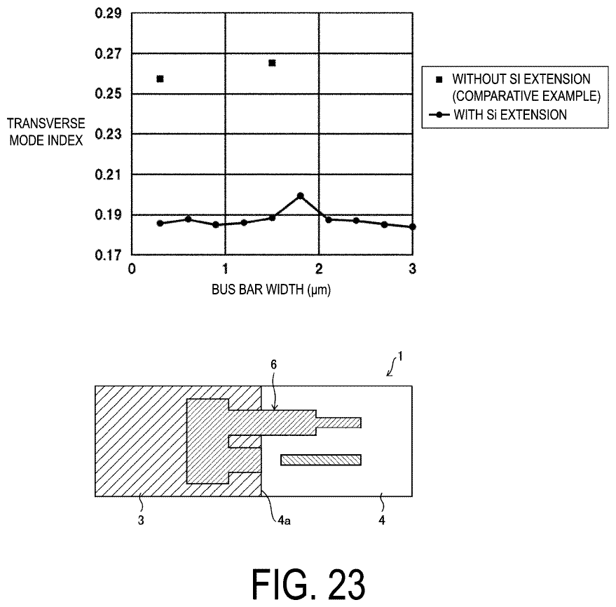

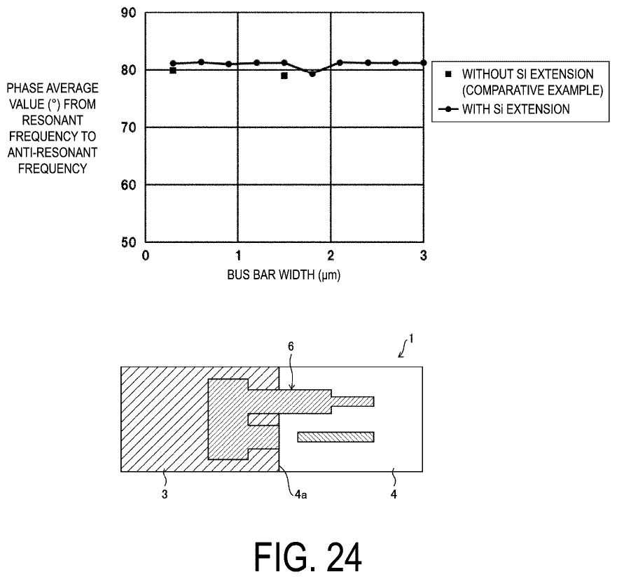

In the elastic wave device 1 according to a seventh embodiment, the width of the bus bar 61 of the IDT electrode 6 is different. FIG. 23 is a graph illustrating a transverse mode index T depending on the width of the bus bar in the elastic wave device 1 according to the seventh embodiment. FIG. 24 is a phase average value from the resonant frequency fr to the anti-resonant frequency fa depending on the width of the bus bar in the elastic wave device 1 according to the seventh embodiment. The silicon extension amount x is assumed to correspond to a case where the silicon extends below the front end of the dummy electrode finger 63.

As illustrated in FIGS. 23 and 24, the transverse mode index T and the phase average value were confirmed not to be affected by changing the width of the bus bar 61.

### Eighth Embodiment

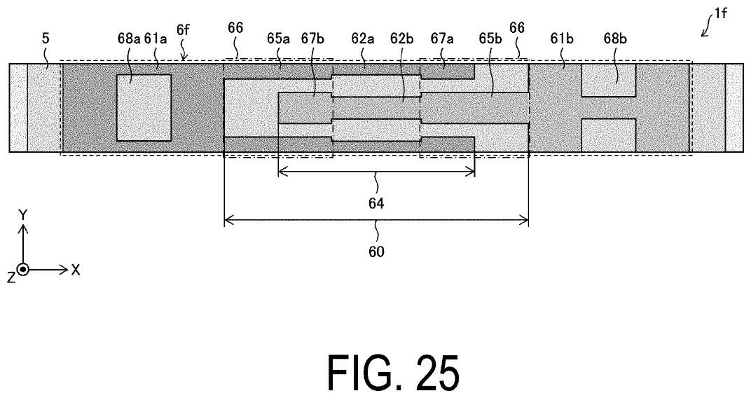

FIG. 25 is a plan view of an elastic wave device according to an eighth embodiment. The elastic wave device includes an IDT electrode 6f as a piston resonator instead of the IDT electrode 6.

The piston resonator includes in the electrode finger 62: a root that is in contact with the bus bar 61 and widens; and a front end of the electrode finger 62, which widens. The both are the widened portion 65 and a widened portion 67, respectively. The piston resonator does not include the dummy electrode finger 63. The bus bar 61 includes an opening portion 68. The widened portion 67 and the opening portion 68 are classified into a widened portion 67a and a widened portion 67b, and an opening portion 68a and an opening portion 68b, according to the applied potential.

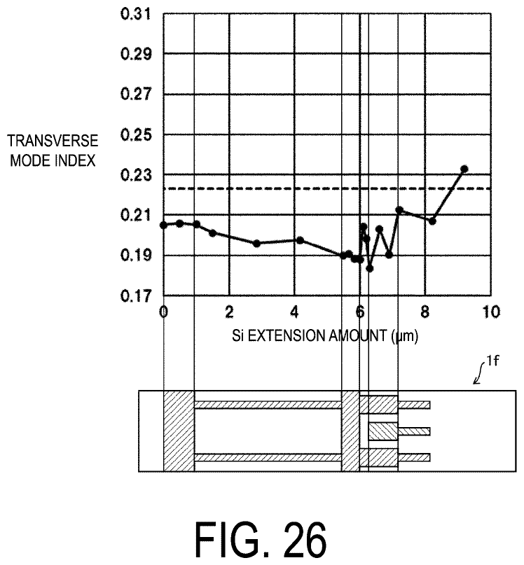

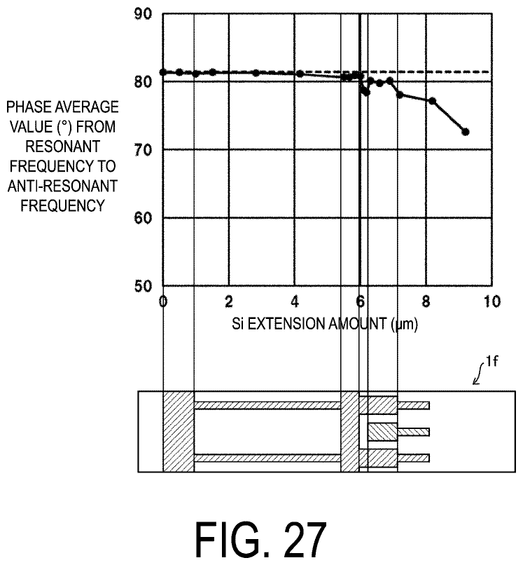

FIG. 26 is a graph illustrating a transverse mode index T depending on the silicon extension amount x in the elastic wave device according to the eighth embodiment. FIG. 27 is a phase average value from the resonant frequency fr to the anti-resonant frequency fa depending on the silicon extension amount x in the elastic wave device according to the eighth embodiment. The dashed lines in FIGS. 26 and 27 are the values in the comparative examples, and the solid lines are the values in the elastic wave device according to the eighth embodiment.

As illustrated in FIG. 26, the transverse mode index T is found to be sufficiently small as compared with the first comparative example until the outer edge 4a reaches the end portion of the low acoustic velocity region 66. As illustrated in FIG. 27, the phase average value is found to be sufficiently close to 90° until the outer edge 4a reaches the end portion of the low acoustic velocity region 66. Thus, in the elastic wave device according to the eighth embodiment, the frequency characteristic is determined to be sufficiently good until the outer edge 4a reaches the end portion of the low acoustic velocity region 66.

### Ninth Embodiment

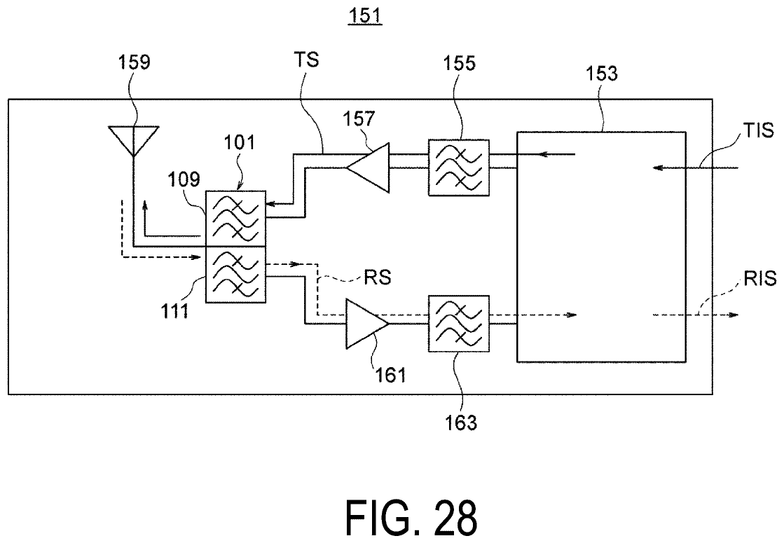

FIG. 28 is a diagram illustrating a schematic configuration of a communication apparatus 151 according to a ninth embodiment. The communication apparatus 151 is an application example of the elastic wave device according to an aspect of the present disclosure, and performs wireless communication using radio waves. The communication apparatus 151 may include one branching filter 101 as a transmission filter 109 and another branching filter 101 as a receiving filter 111. Each of the two branching filters 101 may include an elastic wave device (e.g., elastic wave device 1, 1a to 1f) according to an aspect of the present disclosure. Thus, the communication apparatus 151 may include an elastic wave device according to an aspect of the present disclosure.

In the communication apparatus 151, a transmission information signal TIS containing information to be transmitted may be modulated and frequency raised (converted to a high frequency signal having a carrier frequency) by a RF-IC (Radio Frequency-Integrated Circuit) 153 and converted into a transmission signal TS. A band pass filter 155 may remove unnecessary components for the TS other than a passband for transmission. The TS after removal of unnecessary components may then be amplified by an amplifier 157 and input to the transmission filter 109.

The transmission filter 109 may remove unnecessary components other than a passband for transmission from the input transmission signal TS. The transmission filter 109 may output the TS after removal of unnecessary components to an antenna 159 via the antenna terminal (e.g., TCin described above). The antenna 159 may convert the TS, which is an electric signal input to itself, into a radio wave as a radio signal and transmit the radio wave to the outside of the communication apparatus 151.

The antenna 159 may convert the received external radio wave into a reception signal RS which is an electric signal, and input the RS to the receiving filter 111 via the antenna terminal. The receiving filter 111 may remove unnecessary components other than a passband for reception from the input RS. The receiving filter 111 may output the reception signal RS after removal of the unnecessary components to an amplifier 161. The output RS may be amplified by the amplifier 161. A band pass filter 163 may remove unnecessary components other than the passband for reception from the amplified RS. The RS after removal of the unnecessary components may be frequency lowered and demodulated by the RF-IC153 and converted into a reception information signal RIS.

The TIS and RIS may be low frequency signals (baseband signals) containing appropriate information. For example, the TIS and RIS may be analog audio signals or digitized audio signals. The pass band of the radio signal may be set appropriately and may conform to various known standards.

In the first to eighth embodiments, the low acoustic velocity region 66 is defined by the length of the electrode finger of the widened portion 65 in the extending direction, but not limited to this. More specifically, the low acoustic velocity region 66 may be defined by adding an additional film on the electrode finger 62 in place of the widened portion 65 to increase the weight of at least a part of the electrode finger 62. That is, the frequency characteristic of the elastic wave device may be improved by forming the low acoustic velocity region 66 where the weight per unit length of the electrode finger is increased.

### CONCLUSION

In a first aspect of the present disclosure, an elastic wave device includes a support substrate provided with a cavity portion; a piezoelectric substrate located over the support substrate and covering the cavity portion; and an IDT electrode located on the piezoelectric substrate. The IDT electrode includes: a pair of bus bars; and a plurality of electrode fingers provided in a first region sandwiched between the pair of bus bars. The entirety of an intersecting region in the first region is arranged in a manner to overlap with the cavity portion in plane perspective. The first region includes a low acoustic velocity region, which has an elastic wave acoustic velocity lower than at least part of the other region in the first region, in the arrangement direction of the plurality of electrode fingers, and extends in the arrangement direction. An outer edge of the cavity portion and the low acoustic velocity region overlap with each other in plane perspective.

The above configuration enables to reduce a spurious signal and improve a frequency characteristic.

In an elastic wave device according to a second aspect of the present disclosure, the low acoustic velocity region may include a widened portion provided in a corresponding one of the plurality of electrode fingers in the first aspect.

The above configuration enables the electrode finger to include a low acoustic velocity region, which is widened.

In an elastic wave device according to a third aspect of the present disclosure, the low acoustic velocity region may include an additional film provided on a corresponding one of the plurality of electrode fingers in the first or second aspect.

The above configuration enables the electrode fingers to have a low acoustic velocity region, which includes the additional films.

In an elastic wave device according to a fourth aspect of the present disclosure, the low acoustic velocity region may include a second electrode finger.

The second electrode finger faces a corresponding one of the electrode fingers in the extending direction of the electrode fingers and has a width larger than an average width of the electrode fingers in any one of the first to third aspects.

The above configuration enables the low acoustic velocity region to include a second electrode finger.

In an elastic wave device according to a fifth aspect of the present disclosure, the low acoustic velocity region may be a partial region near a corresponding one of the pair of bus bars in any one of the first to fourth aspects.

The above configuration enables the low acoustic velocity region to be located near a corresponding one of the bus bars.

In an elastic wave device according to a sixth aspect of the present disclosure, the widened portion may be provided on a front end side of the electrode finger in any one of the second to fifth aspects.

The above configuration enables the low acoustic velocity region to be located on the front end side of the electrode finger.

In an elastic wave device according to a seventh aspect of the present disclosure, a distance from the low acoustic velocity region to the intersecting region may be within one wavelength in any one of the first to sixth aspects.

The above configuration enables the low acoustic velocity region to be located up to near the intersecting region.

In an elastic wave device according to an eighth aspect of the present disclosure, a distance from the low acoustic velocity region to the intersecting region may be within a mount pitch of the plurality of electrode fingers in any one of the first to seventh aspects.

The above configuration enables the low acoustic velocity region to be located up to near the intersecting region.

In an elastic wave device according to a ninth aspect of the present disclosure, the bus bars may be provided with a void portion in any one of the first to eighth aspects.

The above configuration enables to provide a void portion in the bus bars.

In an elastic wave device according to a tenth aspect of the present disclosure, the support substrate may be silicon in any one of the first to ninth aspects.

The above configuration enables to employ silicon as the support substrate.

In an elastic wave device according to an eleventh aspect of the present disclosure, the IDT electrode may excite an elastic wave of A1 mode Lamb wave in any one of the first to tenth aspects.

The above configuration enables the IDT electrode to excite an elastic wave of A1 mode Lamb wave.

An elastic wave device according to a twelfth aspect of the present disclosure, may be a communication apparatus including the elastic wave device in any one of the first to eleventh aspects.

The above configuration enables the communication apparatus to perform filtering by the elastic wave device.

### Supplementary Note

The invention according to the present disclosure has been described on the basis of various drawings and examples. However, the invention according to the present disclosure is not limited to the above-described embodiments. In other words, the invention according to the present disclosure can be modified in various ways within the scope illustrated in the present disclosure, and embodiments obtained by appropriately combining the technical means disclosed in different embodiments are also included in the technical scope of the invention according to the present disclosure. In other words, it is to be noted that a person skilled in the art can easily make different variations or modifications based on the present disclosure. It is also to be noted that these variations or modifications are within the scope of the present disclosure.

### REFERENCE SIGNS

1, 1a to 1f, 100 Elastic wave device
2 Support
3 Silicon
4 Cavity portion
4a Outer edge
5 Piezoelectric substrate
6, 6a to 6f, 600 IDT electrode
7a to 7c Connection layer
60 First region
61, 61a, 61b Bus bar
62, 62a, 62b Electrode finger
63, 63a, 63b Dummy electrode finger
64 Intersecting region
65, 65a, 65b, 67, 67a, 67b Widened portion
66 Low acoustic velocity region
68, 68a, 68b Opening portion
151 Communication apparatus

1. An elastic wave device comprising:
a support substrate provided with a cavity portion;
a piezoelectric substrate located over the support substrate and covering the cavity portion; and
an IDT electrode located on the piezoelectric substrate, wherein
the IDT electrode comprises:
a pair of bus bars; and
a plurality of electrode fingers provided in a first region sandwiched between the pair of bus bars,
the entirety of an intersecting region in the first region is arranged in a manner to overlap with the cavity portion in plane perspective,
the first region comprises a low acoustic velocity region, the low acoustic velocity region having an elastic wave acoustic velocity lower than at least part of the other region in the first region, in an arrangement direction of the plurality of electrode fingers, and extending in the arrangement direction, and
an outer edge of the cavity portion and the low acoustic velocity region overlap with each other in plane perspective.

2. The elastic wave device according to claim 1, wherein
the low acoustic velocity region comprises a widened portion provided in a corresponding one of the plurality of electrode fingers.

3. The elastic wave device according to claim 1, wherein
the low acoustic velocity region comprises an additional film provided on a corresponding one of the plurality of electrode fingers.

4. The elastic wave device according to claim 1, wherein
the low acoustic velocity region comprises a second electrode finger facing a corresponding one of the electrode fingers in an extending direction of the electrode fingers and having a width larger than an average width of the electrode fingers.

5. The elastic wave device according to claim 1, wherein
the low acoustic velocity region is a partial region near a corresponding one of the pair of bus bars.

6. The elastic wave device according to claim 2, wherein
the widened portion is provided on a front end side of a corresponding one of the electrode fingers.

7. The elastic wave device according to claim 1, wherein
a distance from the low acoustic velocity region to the intersecting region is within one wavelength.

8. The elastic wave device according to claim 1, wherein
a distance from the low acoustic velocity region to the intersecting region is within a mount pitch of the plurality of electrode fingers.

9. The elastic wave device according to claim 1, wherein
the bus bars are provided with a void portion.

10. The elastic wave device according to claim 1, wherein
the support substrate is silicon.

11. The elastic wave device according to claim 1, wherein the IDT electrode excites an elastic wave of A1 mode Lamb wave.

12. A communication apparatus comprising the elastic wave device according to claim 1.
